(19) United States
(12) Patent Application Publication
(10) Pub. No.: US 2026/0303036 A1
(43) Pub. Date: Oct. 1, 2026

(54) WIDEBAND AMPLIFIER WITH ONE-BIT STEP ATTENUATION

(71) Applicant: NORTHROP GRUMMAN SYSTEMS CORPORATION, Falls Church, VA (US)

(72) Inventor: Seok Bae Park, Columbia, MD (US)

(73) Assignee: NORTHROP GRUMMAN SYSTEMS CORPORATION, Falls Church, VA (US)

(21) Appl. No.: 19/091,180

(22) Filed: Mar. 26, 2025

(51) Int. Cl. H03F 1/42; H03F 1/22; H03F 1/30; H03F 1/56; H03F 3/195

(52) U.S. Cl. CPC H03F 1/42; H03F 1/223; H03F 1/301; H03F 1/302; H03F 1/56; H03F 3/195

(57) ABSTRACT

The wideband amplifier includes a cascoded circuit comprising a first transistor and a second transistor, a third transistor, a first resistor, and a bias control circuit coupled between the first resistor and the third transistor to provide attenuation function of the amplifier. The bias control circuit includes a second resistor and a switch coupled to the second resistor in parallel. The resistor is coupled to the first resistor and a collector of the third transistor in series. The wideband amplifier requires a single bias control circuit, which includes one resistor and one MOSFET switch, to implement attenuation function, which simplifies the design process. The wideband amplifier consumes much less current while providing attenuation, which saves power consumption.

### BACKGROUND

In many radio frequency integrated circuits (RFICs) for radar and space applications, the radio frequency (RF) transmit/receive chains require digital step attenuators to control the overall gain. Those attenuators are implemented as separate blocks, which cost layout area and design time. Integrating attenuation function into an amplifier can save layout area and design time. The problem is how to efficiently add attenuation function into an amplifier. The conventional approach is to add a switchable emitter degeneration resistor while the amplifier bias current is kept constant. Because of the constant amplifier bias current, the conventional approach does not provide any power saving effect. This conventional approach requires multiple switches and quite extensive design effort to implement. Therefore, the conventional approach is quite inefficient, consumes large area, and provides no power saving. Therefore, there is a need to provide a wideband amplifier device in which the attenuation function is efficiently added, providing a compact structure and also power saving effect.

### SUMMARY

The disclosed invention relates to a wideband amplifier with efficient and compact 1-bit digital step attenuation. The wideband amplifier of the disclosed invention has been developed to support a program that requires an amplifier with 8 dB attenuation for its radio frequency integrated circuit (RFIC). A conventional way of adding attenuation function to an amplifier requires multiple switches and design tweaks to vary the gain. The purpose of the disclosed invention is to integrate the attenuation function into an amplifier in a very efficient manner in a very small area. The wideband amplifier of the disclosed invention consumes much less current in attenuation mode than in normal full gain mode. A 1-bit attenuator and an amplifier are integrated into one block. This 1-bit attenuator can be integrated into gain amplifiers as well as power amplifiers.

Contrary to the conventional approach that requires multiple switches and quite extensive design effort to implement, the disclosed invention is just to add one resistor and one switch to the amplifier to lower the reference current, and consequently lower the gain to obtain attenuation. It does not require any tweaks or tuning on the amplifier. Since it requires lower current in attenuation mode, it saves current consumption. It is implemented in a very small area with a very short design time.

These advantages and others are achieved, for example, by a wideband amplifier that includes a cascoded circuit including a first transistor and a second transistor, where an emitter of the second transistor is coupled to a collector of the first transistor in series. The wideband amplifier further includes a third transistor, a first resistor coupled to a supply voltage source, a bias control circuit coupled between the first resistor and the third transistor, an input terminal for receiving an input signal, and an output terminal for outputting an output signal. The base of the third transistor is coupled to the base of the first transistor in series. The bias control circuit is configured to control attenuation. The input terminal is coupled to the bases of the first transistor and the third transistor. The output terminal is coupled to a collector of the second transistor.

Each of the first, second, and third transistors may be an NPN bipolar junction transistor (BJT). The bias control circuit may include a second resistor coupled to the first resistor and a collector of the third transistor in series, and a switch coupled to the second resistor in parallel. The switch may be a metal-oxide-semiconductor field-effect transistor (MOSFET). The collector of the third transistor may be connected to the base of the third transistor.

The wideband amplifier further includes a feedback network configured to extract a portion of the output signal and to feed the portion of the output signal to the base of the first transistor. The feedback network is configured to provide controlled adjustments to a gain of the common emitter device. The wideband amplifier further includes an input matching network coupled between the input terminal and the bases of the first transistor and the third transistor. The input matching network is configured to maximize power transfer between the input terminal and the base of the first transistor. The wideband amplifier further includes an output matching network between the output terminal and the collector of the second transistor. The output matching network is configured to maximize power transfer between the output terminal and the collector of the second transistor. The base of the second transistor and the collector of the second transistor are connected to the supply voltage source to receive a source voltage. The wideband amplifier further includes a first bias network configured to deliver the source voltage to the base of the second transistor. The wideband amplifier further includes a second bias network configured to deliver the source voltage to the collector of the second transistor. The gate of the switch is connected to a control signal source. The switch is turned on or off based on the control signal from the control signal source. The switch may be configured to provide on-resistance when the switch is turned on.

### BRIEF DESCRIPTION OF THE DRAWINGS

The preferred embodiments described herein and illustrated by the drawings hereinafter are included to illustrate and not to limit the invention, where like designations denote like elements.

FIG. 1 shows a circuit diagram of a conventional amplifier in which two emitter degeneration circuits are implemented.

FIG. 2 shows a circuit diagram of a wideband amplifier of the disclosed invention in which a single bias control circuit is implemented.

FIG. 3 shows a Cadence schematic diagram built to test the performance of the wideband amplifier of the disclosed invention.

FIGS. 4A-4D show simulation results for gain, return loss, noise figure, and stability of the wideband amplifier of the disclosed invention, respectively.

### DETAILED DESCRIPTION

The following detailed description is merely exemplary in nature and is not intended to limit the described embodiments or the application and uses of the described embodiments. All of the implementations described below are exemplary implementations provided to enable persons skilled in the art to make or use the embodiments of the disclosure and are not intended to limit the scope of the disclosure, which is defined by the claims. It is also to be understood that the drawings included herewith only provide diagrammatic representations of the presently preferred structures of the present invention and that structures falling within the scope of the present invention may include structures different than those shown in the drawings.

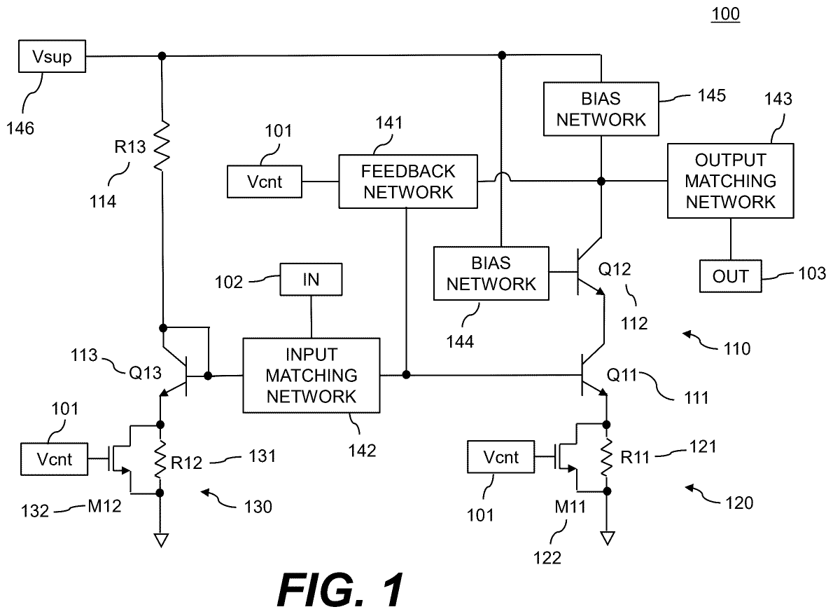

With reference to FIG. 1, shown is a circuit diagram of a conventional amplifier 100 in which attenuation circuit is implemented. The conventional amplifier 100 implements two emitter degeneration circuits 120 and 130. It is still a cascoded common emitter amplifier with one step digitally controlled attenuation. However, emitter degeneration is utilized to lower the gain of the amplifier.

The amplifier 100 includes cascoded circuit 110, which includes common emitter device (first transistor) Q11 111 and second transistor Q12 112, and first emitter degeneration circuit 120. The emitter of the second transistor Q12 112 is coupled to the collector of the first transistor Q11 111 in series. The emitter of the first transistor Q11 111 is coupled to the first emitter degeneration circuit 120 that includes first resistor 121 and first switch M11 122 coupled in parallel. The first switch M11 122 is controlled by a control signal Vcnt from control signal source 101. The control signal Vcnt is applied to the gate of the first switch M11 122 to turn on or off the first switch M11 122.

When the control signal Vcnt is high, the switch M11 122 is turned on and presents a small on-resistance (Ron). Since the parallel combination of the on-resistance Ron and the resistance R11 of the first resistor 121 is quite small, the first transistor Q11 111 is not degenerated and the amplifier provides full gain with no attenuation. When the control signal Vcnt is low, the first switch M11 122 is turned off and the first transistor Q11 111 is degenerated by the first resistor 121, which lowers the gain of the amplifier.

The amount of the resistance R11 of the first resistor 121 will determine how much attenuation it will provide. The problem of this approach is that once the first transistor Q11 111 is degenerated for attenuation, its bias network and feedback network also have to be modified to keep the amplifier stable and functioning in attenuation mode. To do so, another switch M12 132 should be added and other switches should be also added to the feedback network, which really complicates the design process.

As shown in FIG. 1, the amplifier 100 further includes third transistor Q13 113 and second emitter degeneration circuit 130 that includes second resistor 131 and second switch M12 132 coupled in parallel. The base of the third transistor Q13 113 is coupled to the base of the first transistor Q11 111 in series. The collector of the third transistor Q13 113 is coupled to the base of the third transistor Q13 113. The collector of the third transistor Q13 113 is coupled to third resistor 114. The first transistor Q11 111, the third transistor Q13 113, and the third resistor 114 may form a current mirror circuit. The emitter of the third transistor Q13 113 is coupled to the second emitter degeneration circuit 130. The second switch M12 132 is controlled by a control signal Vcnt from control signal source 101. The control signal Vcnt is applied to the gate of the second switch M12 132 to turn on or off the second switch M12 132.

The amplifier 100 includes an input terminal 102 receives an input signal. The input terminal 102 is coupled to the bases of the first transistor Q11 111 and the third transistor Q13 113 through input matching network 142. The input matching network 142 is a circuit configured to provide maximum power transfer between the input terminal 102 and the base of the first transistor Q11 111. The input matching network 142 may include inductors and capacitors to optimize signal transmission. The amplifier 100 includes an output terminal 103 that outputs an output signal. The output terminal 103 is coupled to the collector of the second transistor Q12 112 through output matching network 143. The output matching network 143 is a circuit configured to provide maximum power transfer between the output terminal 103 and the collector of the second transistor Q12 112. The output matching network 143 may include inductors and capacitors to optimize the signal transmission.

The amplifier 100 includes feedback network 141 that is configured to extract a portion of the output signal to be output through the output terminal 103 and to feed the portion of the output signal to the base of the first transistor Q11 111. The feedback network is configured to provide controlled adjustments to the amplifier's gain. In the conventional amplifier 100, the feedback network 141 is controlled by the control signal from the control signal source 101. The amplifier 100 includes bias networks 144 and 145 through which the supply voltage from the supply voltage source 146 is respectively supplied to the base and collector of the second transistor Q12 112.

As shown in FIG. 1 and described above, the conventional amplifier 100 requires multiple design tweaks on bias and feedback networks to make the amplifier stable and functioning in attenuation mode. On top of that, the resulting amplifier performance in attenuation state is not very good due to this complication. Also, in attenuation mode, the amplifier consumes the same amount of current as in normal mode.

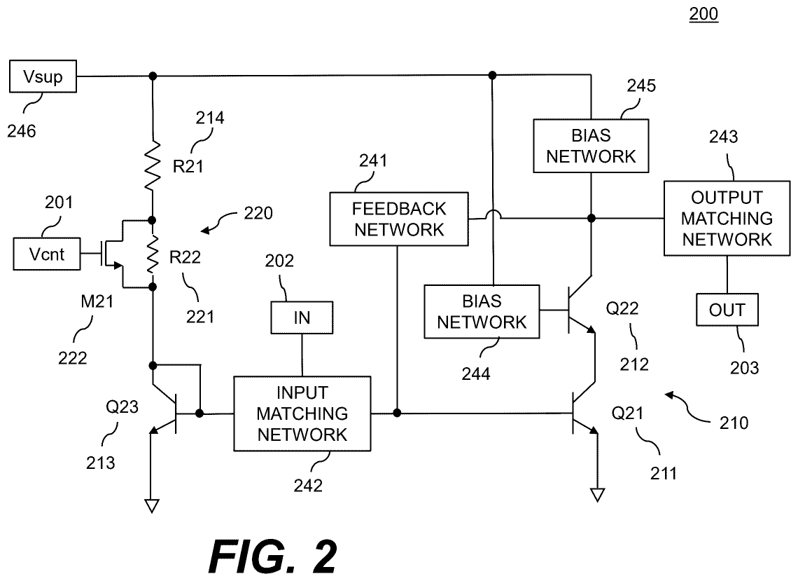

With reference to FIG. 2, shown is a circuit diagram of wideband amplifier 200 of the disclosed invention, in which a single bias control circuit 220 is implemented to control attenuation. The wideband amplifier 200 of the disclosed invention is a cascoded common emitter amplifier with one step digitally controlled attenuation. The wideband amplifier 200 modifies the bias current of the common emitter device to get attenuation or to lower the gain of the amplifier.

The wideband amplifier 200 includes cascoded circuit 210 that includes common emitter device (first transistor) Q21 211 and second transistor Q22 212. The emitter of the second transistor Q22 212 is coupled to the collector of the first transistor Q21 211 in series. The wideband amplifier 200 includes first resistor 214, third transistor Q23 213, and bias control circuit 220 coupled between the first resistor 214 and the third transistor Q23 213. The bias control circuit 220 includes a second resistor 221 and switch M21 222. The bias control circuit 220 essentially changes or controls the bias current. The second resistor 221 is coupled to the first resistor 214 and the collector of the third transistor Q23 213 in series. The switch M21 222 coupled to the second resistor 221 in parallel. The base of the third transistor Q23 213 is coupled to the base of the first transistor Q21 211 in series. The collector of the third transistor Q23 213 is coupled to the base of the third transistor Q23 213. The collector of the third transistor Q23 213 is coupled to the second resistor 221 and the switch M21 222. The first transistor Q21 211, the third transistor Q23 213, and the first resistor 214 may form a current mirror circuit. The switch M21 222 is controlled by a control signal Vcnt from control signal source 201. The control signal Vcnt is applied to the gate of the switch M21 222 to turn on or off the switch M21 222.

The bias current of the first transistor Q21 211 is generated by current mirror circuit including the diode connected third transistor Q23 213 and the first transistor Q21 211. The reference current flowing through the third transistor Q23 213 is determined by the total resistance applied to the collector of the third transistor Q23 213. The larger the total resistance, the smaller the reference current is and the lower the amplifier gain is.

The first transistor Q21 211, second transistors Q22 212, and the third transistors Q23 213 may be NPN bipolar junction transistors (BJTs). The switch M21 222 may be a metal-oxide-semiconductor field-effect transistor (MOSFET). However, the types of the transistors are not limited to those shown in FIG. 2. Different types of transistors may be employed for the wideband amplifier of the disclosed invention as long as the different types provide the same functionalities described in this specification.

When the control signal Vcnt is high, the switch M21 222 is turned on and presents a small on-resistance (Ron). Since parallel combination of the on-resistance Ron and the resistance R22 of the second resistor 221 is quite small, the reference current flowing through the transistor Q23 213 is determined mostly by the resistance R21 of the first resistor 214, and provides full bias current. When the control signal Vcnt is low, the switch M21 222 is turned off and the reference current flowing through the third transistor Q23 213 is determined by series combination of the resistances R21 and R22 of the first and second resistors 214 and 221, in which case the reference current is smaller and the amplifier gain is reduced. In summary, when the control signal Vcnt is high, full bias current is generated and the amplifier provides full gain with no attenuation. When the control signal Vcnt is low, smaller bias current is generated and the amplifier provides attenuation with reduced gain. The amount of the resistance R22 of the second resistor 221 will determine how much attenuation it will provide.

The wideband amplifier 200 includes feedback network 241 that is configured to extract a portion of the output signal to be output through the output terminal 203 and to feed the portion of the output signal to the base of the first transistor Q21 211. The feedback network is configured to provide controlled adjustments to the amplifier's gain. The wideband amplifier 200 includes bias networks 244 and 245 through which the supply voltage from the supply voltage source 246 is respectively supplied to the base and collector of the second transistor Q22 212.

In the wideband amplifier 200 of the disclosed invention, a single (only one) bias control circuit, which includes one resistor and one MOSFET switch, is required to implement attenuation function, which really simplifies the design process compared to the amplifier 100 shown in FIG. 1. The wideband amplifier 200 does not require any design tweaks or tuning on the amplifier. Consequently, the resulting performance of the wideband amplifier 200 in attenuation state is very predictable and excellent due to this simplicity. Moreover, the wideband amplifier 200 consumes much less current while providing attenuation, which saves power consumption.

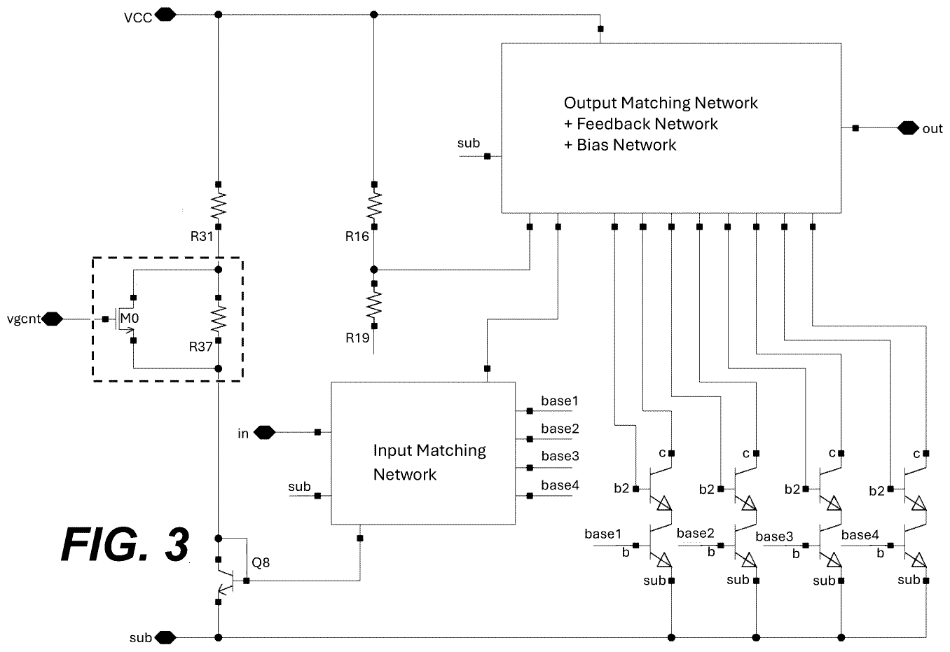

With reference to FIG. 3, shown is a Cadence schematic diagram built to test the performance of the wideband amplifier 200 of the disclosed invention. The wideband amplifier 200 was implemented in 0.18 μm SiGe BiCMOS process and was simulated in Cadence environment. The Cadence schematic diagram shows bias control circuit inside the broken line box, the input matching network in the rectangular block on the lower left side, and output matching networks, feedback network, and bias network in another rectangular block on the upper right side.

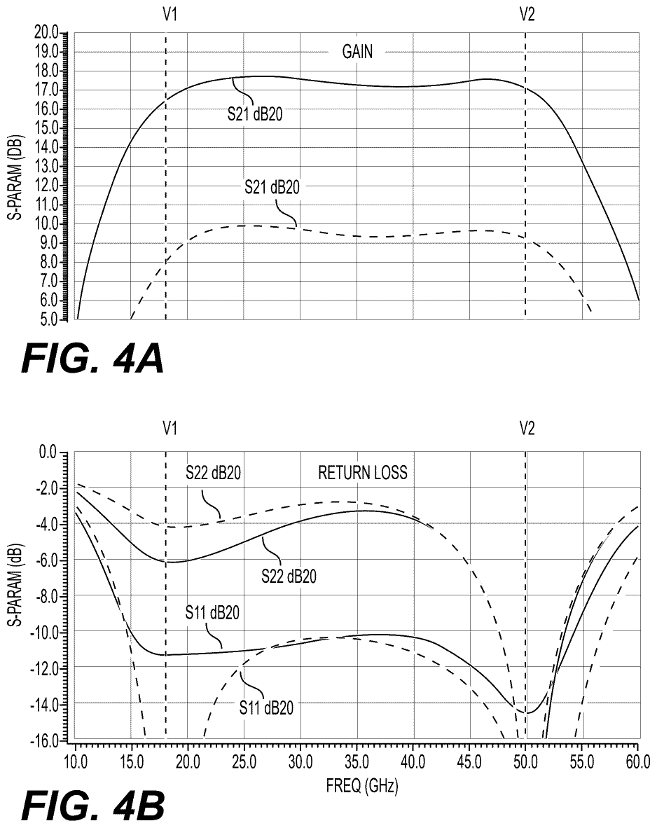

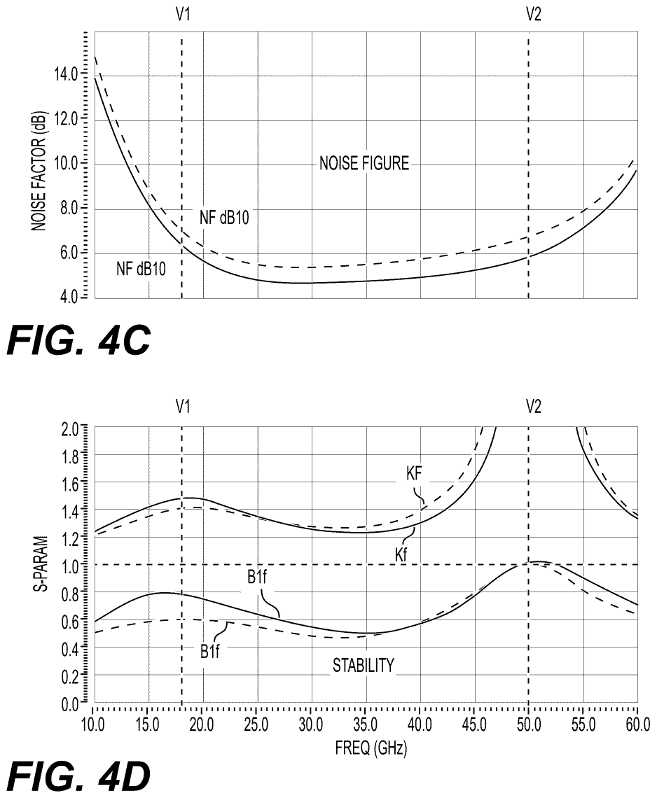

With reference to FIGS. 4A-4D, shown are simulation results for gain, return loss, noise figure, and stability of the wideband amplifier 200, respectively, in the SiGe BiCMOS process. The solid lines represent no attenuation modes (Iccq=33.5 mA), and the dashed lines represent 8 dB attenuation modes (Iccq=9.6 mA).

In the attenuation mode (dash lines), the wideband amplifier 200 provides 8 dB attenuation in the frequency range from 18 to 50 GHz. The wideband amplifier 200 implemented in SiGe BiCMOS process exhibits 17 dB of gain with 8 dB attenuation in the frequency range from 18 to 50 GHz. As shown in FIG. 4A, the gain curve (no attenuation mode) preserves the same shape in attenuation mode. The return loss, noise figure, and stability performance in 8 dB attenuation mode, shown in FIGS. 4B-4D, are very similar to normal mode (no attenuation mode), which is a great advantage of the wideband amplifier 200 of the disclosed invention. In normal or full gain mode, the wideband amplifier 200 consumes 33.5 mA, but it consumes only 9.6 mA in attenuation mode. In other words, in the attenuation mode, the wideband amplifier 200 consumes much less current, which saves power consumption.

Since many modifications, variations, and changes in detail can be made to the described preferred embodiments of the invention, it is intended that all matters in the foregoing description and shown in the accompanying drawings be interpreted as illustrative and not in a limiting sense. Consequently, the scope of the invention should be determined by the appended claims and their legal equivalents.

What is claimed is:

1. A wideband amplifier, comprising:
a cascoded circuit comprising a first transistor and a second transistor, wherein an emitter of the second transistor is coupled to a collector of the first transistor in series;
a third transistor, wherein a base of the third transistor is coupled to a base of the first transistor in series;
a first resistor coupled to a supply voltage source;
a bias control circuit coupled between the first resistor and the third transistor, wherein the bias control circuit is configured to control attenuation;
an input terminal for receiving an input signal, wherein the input terminal is coupled to the bases of the first transistor and the third transistor; and
an output terminal for outputting an output signal, wherein the output terminal is coupled to a collector of the second transistor.

2. The wideband amplifier of claim 1 wherein each of the first, second, and third transistors is an NPN bipolar junction transistor (BJT).

3. The wideband amplifier of claim 1 wherein the bias control circuit comprises:
a second resistor coupled to the first resistor and a collector of the third transistor in series; and
a switch coupled to the second resistor in parallel.

4. The wideband amplifier of claim 3 where the switch is a metal-oxide-semiconductor field-effect transistor (MOSFET).

5. The wideband amplifier of claim 1 wherein a collector of the third transistor is connected to the base of the third transistor.

6. The wideband amplifier of claim 1 further comprising a feedback network configured to extract a portion of the output signal and to feed the portion of the output signal to the base of the first transistor, wherein the feedback network is configured to provide controlled adjustments to a gain of the common emitter device.

7. The wideband amplifier of claim 1 further comprising an input matching network coupled between the input terminal and the bases of the first transistor and the third transistor, wherein the input matching network is configured to maximize power transfer between the input terminal and the base of the first transistor.

8. The wideband amplifier of claim 1 further comprising an output matching network between the output terminal and the collector of the second transistor, wherein the output matching network is configured to maximize power transfer between the output terminal and the collector of the second transistor.

9. The wideband amplifier of claim 1 wherein a base of the second transistor and the collector of the second transistor are connected to the supply voltage source to receive a source voltage.

10. The wideband amplifier of claim 9 further comprising a first bias network configured to deliver the source voltage to the base of the second transistor.

11. The wideband amplifier of claim 9 further comprising a second bias network configured to deliver the source voltage to the collector of the second transistor.

12. The wideband amplifier of claim 1 a gate of the switch is connected to a control signal source, wherein the switch is turned on or off based on the control signal from the control signal source.

13. The wideband amplifier of claim 12 wherein the switch is configured to provide on-resistance when the switch is turned on.
